(19) United States
(12) Patent Application Publication
(10) Pub. No.: US 2008/0144351 A1
(43) Pub. Date: Jun. 19, 2008

(54) METHODS AND SYSTEMS FOR ACCESSING A FERROELECTRIC MEMORY

(76) Inventors: Jarrod Randall Eliason, Colorado Springs, CO (US); Sudhir Kumar Madan, Richardson, TX (US)

Correspondence Address: Peter McLarty, Esq.;Texas Instruments Incorporated, PO Box 655474, M/S 3999, Dallas, TX, 75265, US

(21) Appl. No.: 11/954,371

(22) Filed: Dec. 12, 2007

Related U.S. Application Data
(60) Provisional application No. 60/875,178, filed on Dec. 15, 2006.

(51) Int. Cl. G11C 11/22

(52) U.S. Cl. 365/145

(57) ABSTRACT

One embodiment relates to a method for accessing ferroelectric memory cells in a ferroelectric memory device. A first memory access is performed on the cell, and a second memory access is performed on the cell. An approximately same bias is applied to the bitline and plateline of the cell for a time between the first memory access and the second memory access. Other methods and systems are also disclosed.

### RELATED APPLICATION

This application claims priority to Ser. No. 60/875,178 filed Dec. 15, 2006, which is entitled “Methods and Systems for Accessing a Ferroelectric Memory”.

### FIELD OF INVENTION

The present invention relates generally to semiconductor devices and more particularly to improved methods and systems for ferroelectric memory devices.

### BACKGROUND OF THE INVENTION

Semiconductor memory devices store data and/or program code in personal computer systems, embedded processor-based systems, video image processing circuits, communications devices, and the like. A ferroelectric memory is one type of semiconductor memory device.

Ferroelectric memories store data in ferroelectric capacitors, and are commonly organized in single-transistor, single-capacitor (1T1C) or two-transistor, two-capacitor (2T2C) configurations. In a folded bitline 1T1C architecture, the individual ferroelectric memory cells typically include a ferroelectric (FE) capacitor adapted to store a binary data bit, together with a MOS access transistor, which operates to selectively connect the FE capacitor to one of a pair of complementary bitlines (bit lines), with the other bitline being connected to a reference voltage for read operations. The individual cells are commonly organized as individual bits of a corresponding data word, where the cells of a given word are accessed concurrently by activation of platelines (plate lines) and wordlines (word lines) by address decoding control circuitry.

Ferroelectric memory devices provide non-volatile data storage where the cell capacitors are constructed using ferroelectric dielectric material that may be polarized in one direction or another in order to store a binary value. The ferroelectric effect allows for the retention of a stable polarization in the absence of an applied electric field due to the alignment of internal dipoles within perovskite crystals in the ferroelectric material. This alignment may be selectively achieved by application of an electric field in a first direction that exceeds a coercive field of the material. Conversely, reversal of the applied field reverses the internal dipoles, wherein the response of the polarization of a ferroelectric capacitor to the applied voltage may be plotted as a hysteresis curve.

FIGS. 1A-1C illustrate a portion of a ferroelectric memory device 100 organized in a folded bitline architecture, including a segment (e.g., a 32K segment) in FIG. 1A with 512 rows (words) and 64 columns (bits) of data storage cells 102 indicated as C_{ROW-COLUMN}, where each column of cells 102 is accessed via a pair of complementary bitlines BL_{COLUMN} and BL_{COLUMN}′. In the first row of the device 100, for example, the cells C1-1 through C1-64 form a 64 bit data word accessible via complementary bitline pairs BL1/BL1′ through BL64/BL64′ by activation of a wordline WL1. The cell data is sensed during data read operations using sense amp circuits 104 (S/A C1 through S/A C64) associated with columns 1 through 64, respectively.

As illustrated further in FIG. 1B, an exemplary cell 102a is formed as a 1T1C cell including a single ferroelectric cell capacitor C_{FE}1 and an access transistor 106a. The access transistor 106a serves to connect the cell capacitor C_{FE}1 between one of the complementary bitlines BL1 associated with the cell column and a plateline PL1. During memory accesses, the other bitline BL1′ is selectively connected to a reference voltage generator 108 or 108′ via one of a pair of switches 108a, 108b (FIG. 1A), depending upon which word is being accessed.

FIG. 1C provides a simplified timing diagram 120 showing waveforms or signals on various nodes during a read and restore operation in the device 100 to access cells along WL1. As shown, to read the data stored in the cell, a voltage V_{wl} is applied to wordline WL1, wherein the V_{wl} is typically greater than or equal to a supply voltage Vdd plus a threshold voltage of the transistor 106a, thereby turning on the transistor 106a and coupling the bitline BL1 to the capacitor C_{FE}1. The plateline PL1 is then pulsed high, causing the cell capacitor C_{FE}1 to discharge charge through the transistor 1 06a to the bitline BL1, thereby causing the bitline voltage BL1 to rise. The amount by which the bitline voltage BL1 rises depends upon the state of the ferroelectric capacitor being accessed. To determine whether the state of the ferroelectric capacitor being accessed is a “1” or a “0”, one differential input terminal of the sense amp 104 is coupled to the cell bitline (e.g., data bitline BL1) and the other differential sense amp input is coupled to a reference voltage (e.g., reference bitline BL1′ in this example). To activate the sense amp 104, a sense amp enable signal SE is then taken high. Depending upon whether the cell bitline BL1 is high or low relative to the reference voltage BL1′, the sense amp returns a “1” (e.g., voltage taken to the high rail on BL DATA “1”) or a “0” (e.g., voltage taken to the low rail on BL DATA “0”) as the stored data value for cell 102a.

After the read is complete, an indefinite time may exist where, for example, a user can alter the data on the input pins of the memory device to new data prior to performing a restore associated with the previous read. During this indefinite time, conventional ferroelectric memory designs maintain some bias between plate lines and bit lines in the array. For example, the access depicted in FIG. 1C drives the plate line high during the indefinite period of time while the bit lines may be driven either high or low by the user. Other access schemes may hold the plate line low while any number of bit lines may be driven high. Even in the case wherein the plate line is held low and the bit lines are temporarily isolated from external data, array bias could persist due to non-zero voltage remaining on the bit lines from the read operation.

Because switching or polarization reversal may occur during the read operation, read operations are said to be “destructive” (i.e., the memory cell loses its content when it is read) and are generally followed by a restore operation. Thus, the original stored data can be restored to the cell 102a, for example, by leaving the plateline high for a time after the restore is initiated and then taking the plateline low. If the array data remains unchanged by the user, the operation is considered a data restore. If any array data has been modified by the user prior to the restore, the operation is considered a write.

During the indefinite time between the read and the restore or write which could theoretically last up to the life of the product (e.g., several years), the bitlines and or the plateline could have non-zero bias. This non-zero bias can cause the FeCAP (cell capacitor) of the access cell to be under voltage stress and degrade its properties. Additionally, the pass gates for the un-accessed cells could have charge leakage between the bitlines and their respective storage nodes, thereby disturbing the voltage on the storage nodes of the un-accessed cells and causing non-zero bias to be applied to the FeCAP of these cells. The voltage disturbance on the storage nodes and the stress on the FeCAP can degrade signal margin for subsequent accesses and even destroy the stored data state.

Therefore, a need has arisen to prevent bias across the FeCAPs as well as the leakage between the storage nodes and bitlines during the indefinite time to improve the signal margins. Given the technological complexity of ferroelectric memories, these products require significant capital expenditures to be developed and successfully delivered to the marketplace. Thus, innovation is critical in ferroelectric memories and other semiconductor devices.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

One embodiment relates to a method for accessing ferroelectric memory cells in a ferroelectric memory device. A first memory access operation is performed to access one or more selected ferroelectric memory cells associated with a ferroelectric memory array. A bias of approximately zero volts is applied between the plate lines and bit lines of the memory array for at least a time between the first memory access operation and a second memory access operation.

The following description and annexed drawings set forth in detail certain illustrative aspects and implementations of the invention. These are indicative of only a few of the various ways in which the principles of the invention may be employed.

### BRIEF DESCRIPTION OF THE DRAWINGS

FIG. 1A is a schematic diagram illustrating a portion of a conventional 1T1C folded bitline ferroelectric memory device;

FIG. 1B is a schematic diagram illustrating a 1T1C cell and an associated sense amp in the device of FIG. 1A;

FIG. 1C is a waveform diagram illustrating a conventional read and restore operation in the cell of FIGS. 1A and 1B;

FIGS. 2A-2F are schematic diagrams illustrating an exemplary ferroelectric memory device having a common plateline pulse system in accordance with another aspect of the invention;

FIGS. 3A-3C are schematic and timing diagrams illustrating unwanted charging or discharging of a storage node;

FIGS. 4A-4B are flowcharts illustrating memory access operations in the device of FIGS. 2A-2F; and

FIG. 4C is a timing diagram illustrating one read and restore memory access operation in the device of FIGS. 2A-2F.

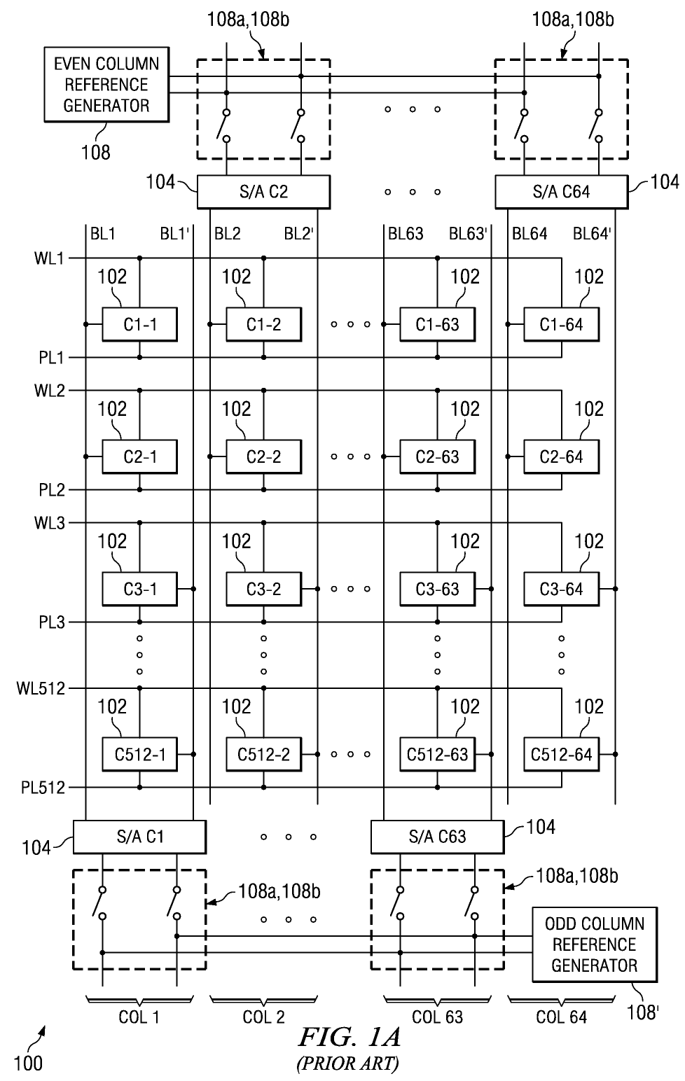

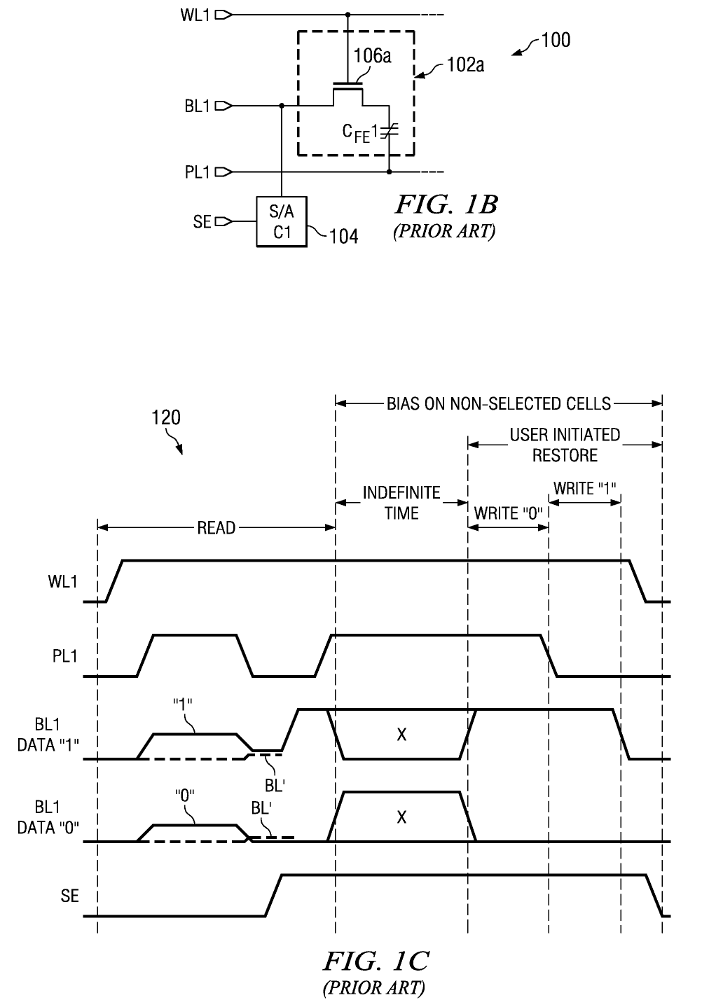

### DETAILED DESCRIPTION OF THE INVENTION

One or more implementations of the present invention will now be described with reference to the attached drawings, wherein like reference numerals are used to refer to like elements throughout.

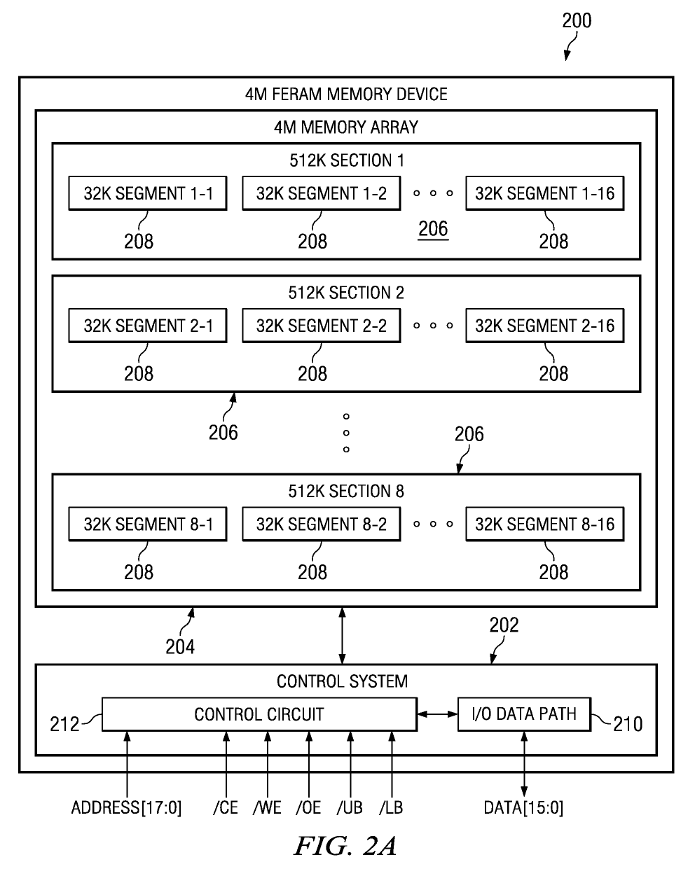

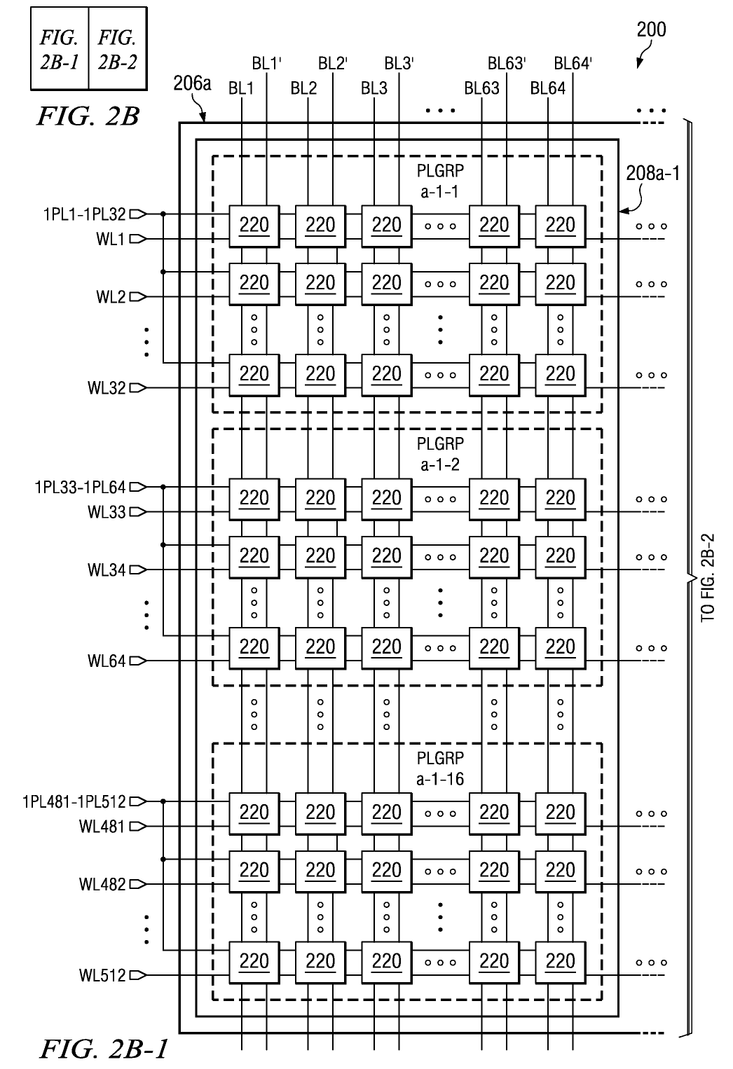

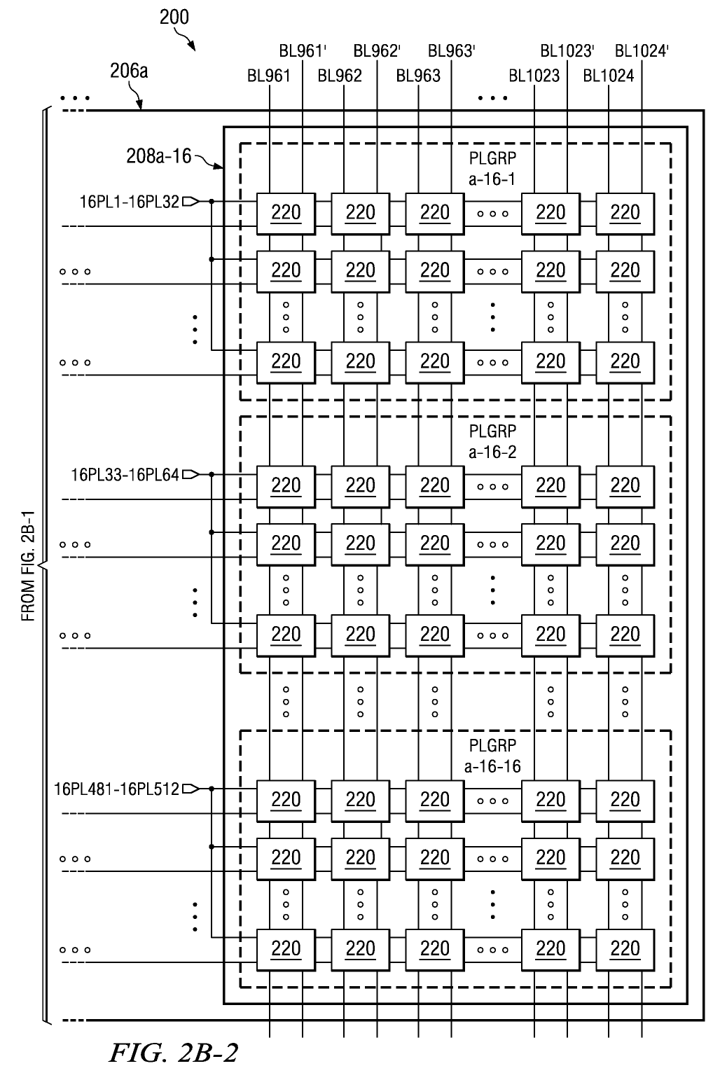

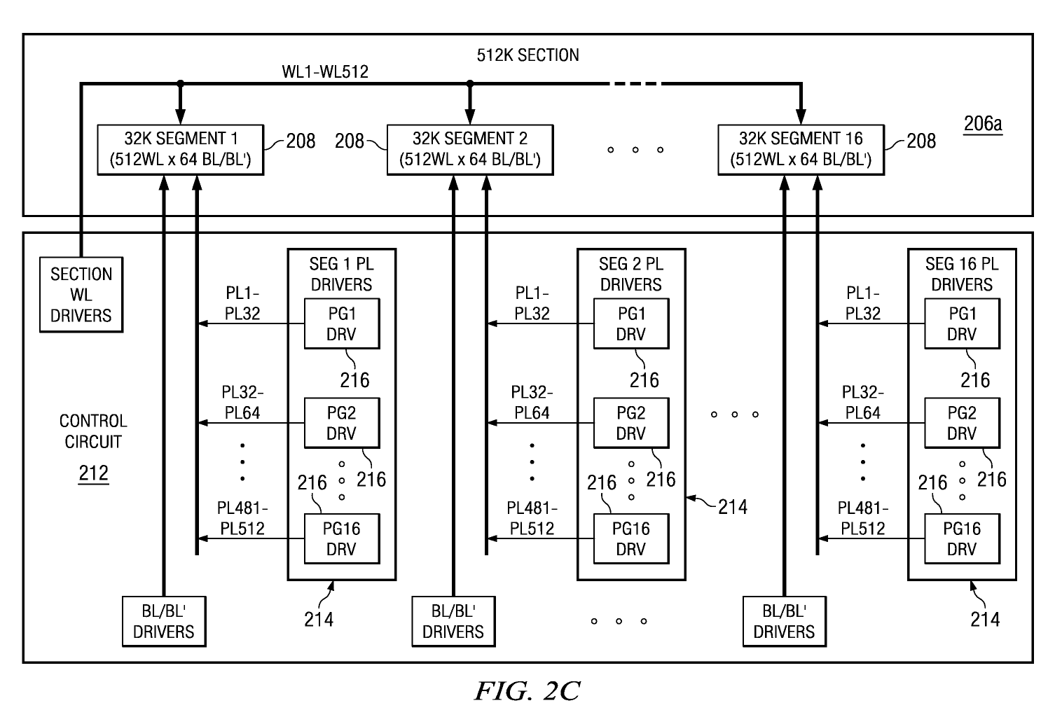

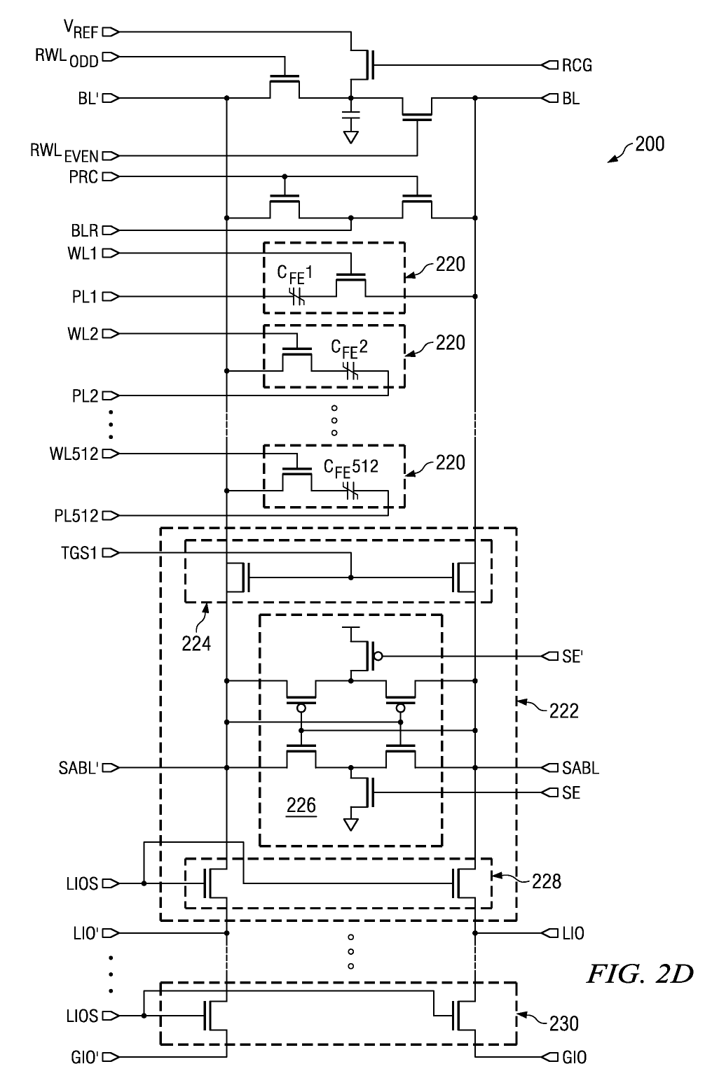

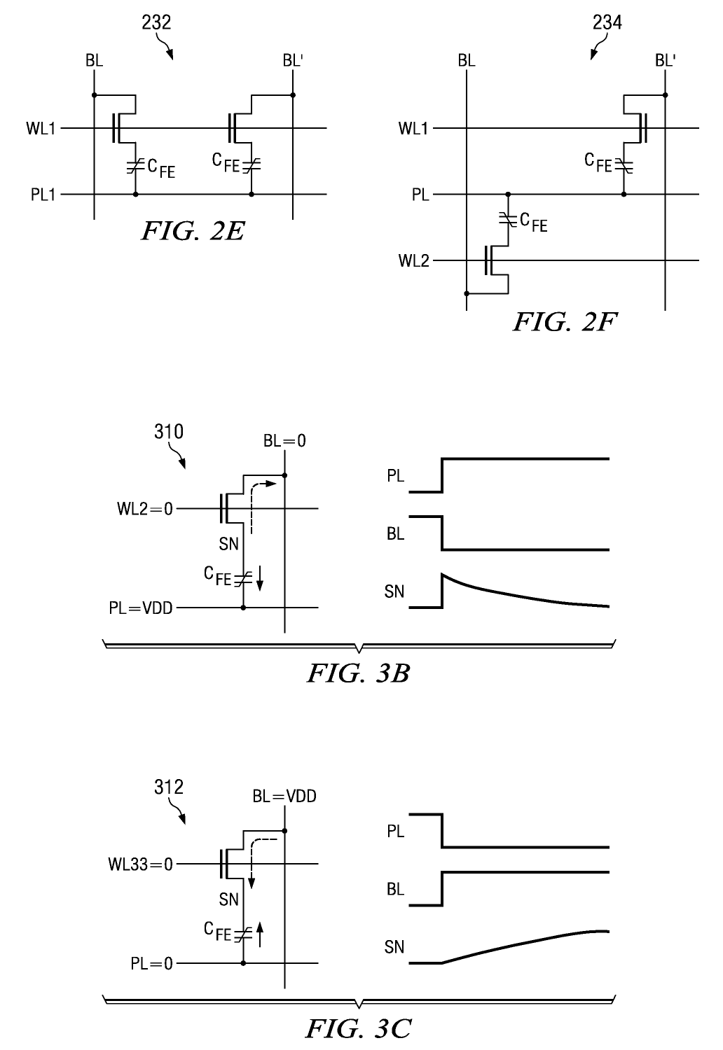

Referring now to FIGS. 2A-2F, one aspect of the invention provides semiconductor devices and control circuits or systems therefore to limit the bias that is applied to nodes of a selected and or non-selected ferroelectric memory cell associated with an accessed column in a ferroelectric memory array during at least a portion of a memory access operation.

As shown in FIG. 2A, one exemplary device 200 is a 4M ferroelectric memory, including a control system 202 and a 4M memory array 204 including eight 512K memory sections or blocks 206. Each memory section 206 is further divided into sixteen segments 208 of 32k each. The control system 202 includes an I/O data path 210 and a control circuit 212 that is coupled to the array 204 to generate wordline and plateline signals according to decoded address information or signals for read, restore, and write operations (e.g., chip enable (CE), write enable (WE), output enable (OE), upper byte enable (UB), lower byte enable (LB), address [17:0], and data[15:0]). In the exemplary device, the 64 columns in a segment are further sub-divided into 4 sets of 16 columns.

As shown in FIG. 2B, one exemplary section 206a is divided into sixteen segments (208a-1, . . . , 208a-16). Each exemplary segment (e.g., 208a-1) includes memory cells 220 that are coupled to platelines and is partitioned into plate groups (e.g., PLGRP a-1-1; PLGRP a-1-2; . . . ; PLGRP a-1-16), wherein each plate group includes 32 rows of memory cells and has a common plate line driver coupled to all the platelines in the plate group. In the exemplary device 200, the wordlines extend across (e.g., are shared among) multiple segments within a given section 206a, wherein the wordline drivers for each section 206a may comprise part of the control circuit 212.

As FIG. 2C shows, the exemplary device 200 provides plateline driver circuits or systems 214 that are associated with individual 32k segments 208. The plateline driver circuit 214 for each segment 208 comprises a plurality of plateline drivers 216 (e.g., PG1 DRV, PG2 DRV, . . . , PG16 DRV) which may also form a part of the control circuitry 212, and which are individually associated with corresponding memory segments 208, wherein a given plateline driver 216 is shared within a segment 208 among the rows of cells that form a plate group. Normally, one or more cells from only one selected segment are accessed a time. But in some circuits the cells from more than one selected segment may be accessed simultaneously. Typically, however, none of the plateline drivers associated with unselected segments is activated during an access because the bitlines of the unselected segments are held at 0V. Further, the exemplary device includes bitline drivers, which are typically associated with sensing circuits that are capable of coupling and decoupling the bitlines from external bitlines associated with the I/O pins of the memory device.

FIG. 2D shows one such sensing circuit 222 capable of coupling and decoupling the bitlines from external bitlines or data IO lines, in the context of a single column of the memory device. As illustrated, the sensing circuit 222 includes a first coupling circuit 224 that couples and decouples the memory cells 220 to and from sense amp 226. The sensing circuit 222 also includes a second coupling circuit 228 that couples and decouples the sense amp 226 to and from local IO lines LIO/LIO′. Third coupling circuit 230 couples and decouples the local IO lines to and from the external bitlines associated with the IO pins of the memory device (GIO/GIO′). Although not shown, the device may also include precharge or biasing circuits to facilitate faster memory access operations. The exemplary device is shown to consist of complimentary pairs of local IO lines LIO/LIO′ and global IO pins GIO/GIO′ also called external bitlines. However, it is not necessary to have complimentary pairs. Circuits can be designed with single sided local IO's and global IO's or external bitlines.

As shown in FIG. 2E and 2F, a memory cell generally includes one or more cell transistors and cell capacitors, and may be configured in, for example, a 2T2C configuration (memory cell 232 in FIG. 2E) or a 1T1C configuration (memory cell 234 in FIG. 2F). The bitcell capacitors C_{FE} may be fabricated from any appropriate ferroelectric material in a wafer, such as Pb(Zr,Ti)O₃ (PZT), (Ba,Sr)TiO₃ (BST), SrTiO₃ (STO), SrBi₂Ta₂O₉ (SBT), BaTiO₃ (BTO), (Bil-xLax) 4Ti₃O₁₂ (BLT), or other ferroelectric material fabricated between two conductive electrodes to form a ferroelectric capacitor C_{FE}. It is noted that the exemplary memory cells 220 include n-channel (NMOS) cell transistors. In alternative embodiments, the cell transistors are p-channel (PMOS) where and various bias conditions are complementary to those described for an n-channel cell transistor.

In ferroelectric memories utilizing a common plateline driver configuration, accessing a selected target row in an array segment could cause unwanted charging or discharging of storage nodes (e.g., storage node disturbance) associated with unselected cells within the selected plate group, or other cells in non-selected plate groups, typically by current leakage of the unselected cell transistor. This unwanted storage node charging or discharging could also occur in conventional non-shared plateline configurations as well. Such unintended charge transfer can degrade signal margins that are required to accurately and repeatably sense the data stored in ferroelectric memory cells.

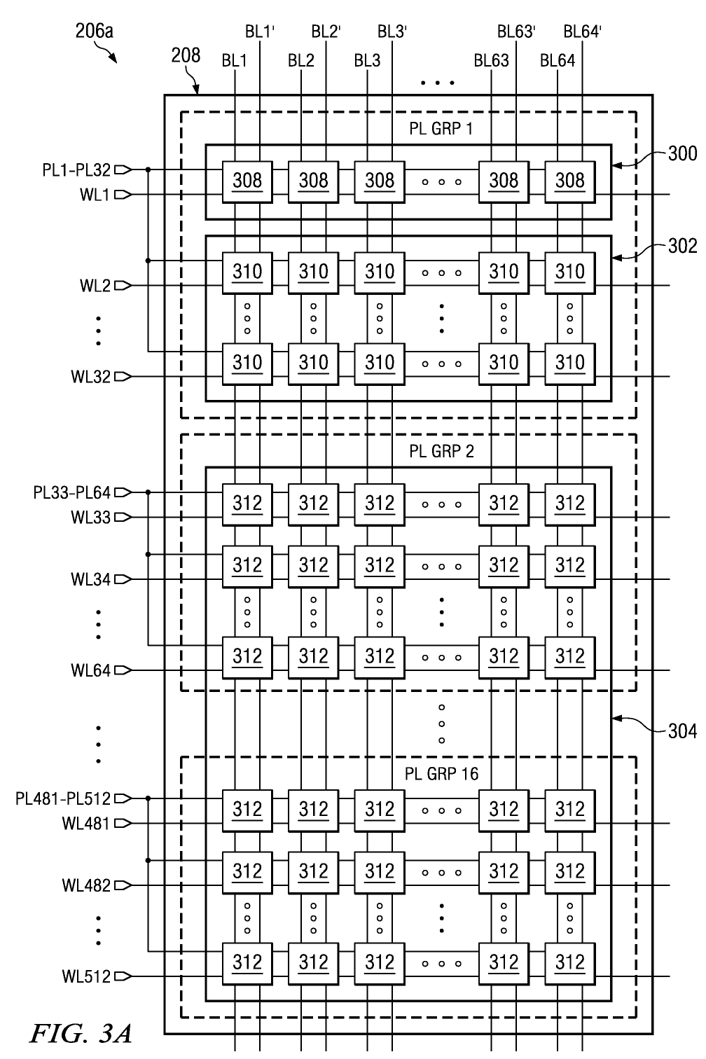

FIGS. 3A-3C discuss examples that illustrates two scenarios in which unwanted storage node charging could occur in a memory array 200, absent countermeasures. For purposes of this example, it is assumed that the memory cells 308 (in region 300 of FIG. 3A) associated with WL1 are being accessed, wherein WL1 is driven high and 1PL1-1PL32 is pulsed high and then low to access data in the memory array. Typically, little or no unwanted node charging would occur to cells 308 in region 300 because WL1 is enabled, causing the cells' transistors to be ON and coupling the cells' capacitors C_{FE} and the bitlines. However, the active cells in region 300 may experience bias voltage across the ferroelectric capacitors for long indefinite periods of time in conventional ferroelectric memories, which may degrade the reliability of the cell.

The memory cells 310 in region 302 are in the selected plate group (PL GRP1) but are not selected for a read or write access (e.g., WL2-WL32 are low and transistors in the associated memory cells 310 are theoretically off). Access to the segment along bitlines BL1-BL64′ may cause the associated bitline voltages to have a low value (e.g., around 0V), while the plate group in region 302 has a high voltage. Thus, the storage node (SN) of the non-accessed cells 310 in region 302 can leak charge (voltage) as shown in FIG. 3B. As shown in FIGS. 3B-3C, the storage node (SN) is the node connecting the cell capacitor C_{FE} and the cell transistor.

By comparison, the memory cells 312 in region 304 (FIG. 3A) are not in the selected plate group and are not selected for a read or write access (e.g., WL33-WL512 are low). Access to the segment 208 along the bitlines BL1-BL64′ may cause the bitline voltages to rise above 0V to a value as much as VDD, while the plate groups in region 304 could remain low. Thus, the storage node of the non-accessed cells 312 in region 304 can acquire charge (voltage) as shown in FIG. 3C. This storage node charging could also occur in region 302 during the time the 1PL1-1PL32 is driven low.

Thus one aim of one embodiment of the invention is to limit the voltage-time stress experienced by the ferroelectric capacitors. Further, any gain or loss in voltage in regions 302 or 304 may not be fully discharged before the beginning of a next cycle and during a time when a segment is repeatedly accessed and these charge gain disturbances can accumulate over a number of cycles, thereby decreasing the signal margin of the system, and possibly depolarizing the cell capacitor C_{FE} from its intended (e.g., programmed) state. Consequently, there is a need for improved ferroelectric memory devices and techniques by which cell storage node disturbances can be mitigated or avoided.

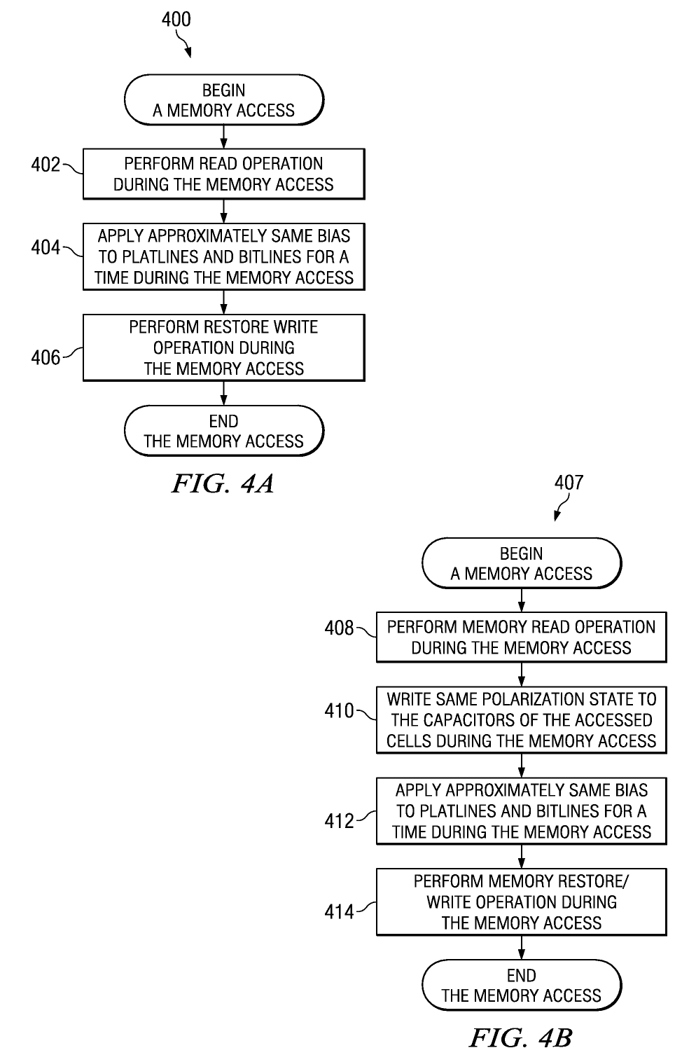

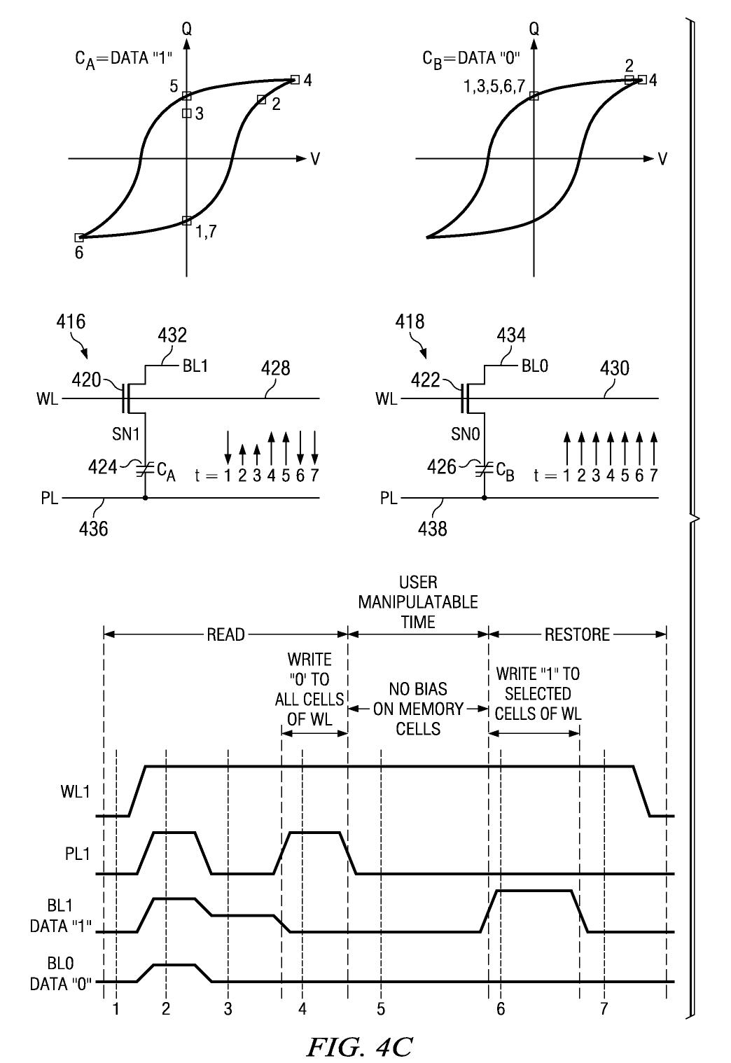

FIGS. 4A-4B are illustrated methods by which ferroelectric memory cells can be read and restored or written so as to mitigate or avoid cell storage node disturbance. Other methods including method of reading and writing to ferroelectric memory cells are also contemplated as falling within the scope of the present invention. Referring initially to FIG. 4A, the methods of the invention provide selective biasing of the platelines and bitlines associated with one or more ferroelectric memory cell storage nodes so as to combat storage node charge accumulation during memory access operations. The inventors have appreciated that storage node disturbance in the form of acquired charge in conventional ferroelectric devices may have a cumulative effect over a number of access cycles to a ferroelectric memory array or segments or other portions thereof, leading to degradation in signal margin and possibly to depolarization of ferroelectric cell capacitors.

To combat these adverse effects, the present invention provides methods for applying a bias of approximately zero volts between the bitlines and platelines for the accessed as well as un-accessed data cells in an accessed column, segment or an array during the indefinite time period between the read and the write operation. Applying the same plateline and bitline bias to the unaccessed cells will tend to move the storage nodes of these cells to almost the same plateline or bitline voltage level because the storage node is floating, thus preventing bias across the FeCAP and leakage across the transistor. For an accessed cell, applying the same bias to the plateline and bitline will directly apply 0V to across the FeCAP. In the exemplary device 0V is applied to the platelines and bitlines during the indefinite time period between the read and write operations. Applying the supply voltage VDD, an intermediate voltage level between 0 and VDD, or higher than VDD are some other options. The invention is not limited to the illustrated implementations, and other methods and apparatus for applying the same bias to the platelines and bitlines are contemplated as falling within the scope of the invention and the appended claims.

An exemplary method 400 is illustrated in FIG. 4A-4C for accessing memory cells in a ferroelectric memory device, wherein a bias voltage of approximately zero volts is applied to the platelines and bitlines of the memory cells to limit storage node disturbances in accordance with an aspect of the present invention. While the method 400 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the devices and systems illustrated and described herein as well as in association with other structures not illustrated. For instance, the methods of the invention may also be carried out in ferroelectric memory devices that do not employ shared plateline drivers.

As shown in FIG. 4A, one embodiment of the invention relates to a method 400 of accessing memory. In step 402, a first read memory access operation is performed to access one or more selected ferroelectric memory cells associated with one or more columns of a ferroelectric memory array. In step 404, an approximately same bias value is applied to the platelines and bitlines associated with the accessed columns for a time. In step 406, after the step 404, a second memory access operation of restore or a write is performed.

As shown in FIG. 4B, one embodiment of the invention relates to a method 407 of accessing memory. In step 408, a read operation is performed to read data from one or more selected ferroelectric memory cells associated with one or more columns. In step 410, a same polarization state is written to all accessed capacitors. In step 412, approximately a same bias value is applied to the platelines and bitlines associated with the accessed columns for a time. In step 414, after the step 412, a restore or a write operation is performed.

As shown in FIG. 4C, one embodiment of the invention is presented with reference to two 1T1C ferroelectric memory cells (416, 418) including NMOS transistors (420, 422, respectively) and ferroelectric capacitors (424, 426, respectively). The gates of the two transistors (416, 418) are connected to the word-lines (428, 430, respectively), which are brought high to access the respective memory cells. The bit-line, (432) bl1, and the other, bit-line bl0, (434) are tied to two separate sense amplifiers for 1T1C configuration (or to a single sense amplifier for a 2T2C configuration), which is in turn are connected to the I/O pins via the data path. The plate-lines (436, 438) are connected to the one electrode of the ferroelectric capacitors (424, 426, respectively). In this discussion, memory cell 416 has an initial stored value of “1” and memory cell 418 has an initial stored value of “0” according to the adopted sign convention. In the adopted sign convention, a positive polarization corresponds to a positive voltage on the plate line and zero voltage on the bit line. In other words, a logical ‘0’ is represented by a positive stored polarization, and a logical ‘1’ is represented by negative stored polarization. The basis of this convention is that it establishes a higher voltage on the bit line when the plate line is pulsed as a logical ‘1’ capacitor will be switched from the negative to positive state, while the logical ‘0’ will not be switched. Note that other sign conventions are contemplated as falling within the scope of the present invention. As previously stated, exemplary devices may also be operated in 2T2C mode or other modes.

One example of a method of performing a read and restore operation is now discussed as could be performed in the illustrated 1T1C memory cells 416 and 418. At time 1, the data stored in the cell 416 is a ‘1’. The true capacitor, C_{A}, is polarized to the ‘1’ state. Conversely, the data stored in the complement capacitor, C_{B}, is polarized to the ‘0’ state. In the figure, the arrows represent the polarization state, with the arrows pointing from positive to negative.

At time 2 in FIG. 4C, wl has been brought high to access the cells. pl is pulsed high, which switches the dipoles in C_{A} and reinforces the dipoles on C_{B}. The dipole reversal on C_{A} dumps a significant P charge onto bl1, while a smaller U charge is dumped onto bl0. The voltage established on bitline for sensing reduces the voltage applied across the capacitor (i.e. interrogation voltage) such that C_{A} may not be completely switched into the ‘0’ state.

At time 3 in FIG. 4C, pl is returned low. Returning pl low before sensing is referred to as UP-DOWN pulsing and may improve opposite state retention characteristics. Although UP-ONLY sensing may be preferred in some embodiments, UP-DOWN sensing may be preferred in others. Once pi is low, a sense amplifier senses the voltage on the bitlines. In typical embodiments, the sense amplifier (e.g., FIG. 2D) is not directly tied to the bit lines and sensing can occur without automatic write back. In FIG. 2D, turning off the TGS1 signal after the time 3 but before the sense-amplifier is enabled will de-couple the sense amp from the bitlines to prevent automatic write back.

At time 4 in FIG. 4C, pl is pulsed high a second time, and both bit lines are precharged to ground. This is possible due to the isolated nature of the sense amp and serves to write both C_{A} and C_{B} into a strong ‘0’ polarization state. One advantage of this approach is that write-back phase of the cycle need only write back 1's, and this can be done without additional plate pulses. In addition, this high pulse duration can be controlled via internal timing on the memory device, such that the reliability of the part may be improved by limiting user intervention. One exemplary sense amp that is capable of providing the desired functionality is described in the FIG. 2D wherein the bitlines can be biased to ground via the node BLR and by activating the bitline precharge control signal PRC.

At time 5 in FIG. 4C, pl is brought low and the bit lines are held at ground.

This zero bias condition can be maintained indefinitely, which eliminates concern for voltage disturb in unselected cells on the selected columns and concern for voltage stress on FeCAP of the selected cells. During this indefinite time, the sense amp decouples the external bit lines associated with the I/O pins of the chip from the bit lines (bl1 and bl0) directly connected to the memory cells. Thus, a user can apply a voltage to the I/O pins of the memory device during this time period, but the voltage need not be applied to the bitlines of the array. By decoupling the external bit lines from the bit lines during this time, the memory device can keep a bias of approximately zero volts applied to the memory cells of the memory array, thereby limiting unwanted charging or discharging of storage nodes.

At time 6 in FIG. 4C, the bit line precharge (FIG. 2D) has been released, 20 sense amplifiers couple with the bl1 and bl0 (by turning on the TGS1 signal in FIG. 2D) and bl1 is driven high by the sense amp and a bit line restore circuit (consists of p-ch pull-up circuit not shown) to restore the ‘1’ state sensed during the read back into C_{A}. Alternatively the bl1 stays low if opposite state data is to be written. Similarly bl0 will stay low if a data state 0 is to be restored. Alternatively, bl0 is driven high if opposite state 1 is to be written.

At time 7 in FIG. 4C, both bl1 and bl0 have been discharged (precharged to 0) with wl on to discharge sn1 and sn0 to ground. Some discharge of the storage nodes is advantageous to prevent destructive overshoot in subsequent accesses to different cells in the same plate group. Finally, wl is brought low in preparation for accessing a new row.

In another embodiment, the bl1 and bl0 are pulsed high before the 2^{nd} plate pulse is turned high to write a 1 polarization state in the capacitors C_{A} and C_{B}. The platelines for the unselected plate groups in the accessed columns are also pulsed high so that the voltage on the platelines and bitlines for the accessed columns are at the same bias to mitigate the storage node voltage disturb issues. The voltage across the FeCAP of the accessed cells is 0V to prevent FeCAP stress. This bias condition for the bitlines and platelines can continue for the user determined indefinite time period until it is time to restore or write the data in the cells. At that time the bitlines are coupled to the sense amplifies for a restore operation and to data input lines via sense amplifiers for a write operation. Next, the platelines are pulsed low. Finally, all the bitlines are pulsed low and the wl signal is deactivated in preparation for accessing a new row.

For a 2T2C configuration, during the user indefinite time, bitlines and their complimentary bitlines are all biased at the same voltage as the platelines associated with the selected columns. The individual cell capacitors are all written 0 or 1 polarization state. For a 0 state, the bitlines and the complimentary bitlines for the selected columns will be a 0V while the plateline for the selected cells transition from high to 0V and held at 0V. The platelines for the unselected cells associated with the selected columns are held at 0V through out the cycle.

For a 1 state, the bitlines and the complimentary bitlines are held high while the plateline of the selected cells transition transitions from low to high and held at high. The platelines for the unselected cells from the selected columns are held high during the user determined indefinite time to provide 0V bias between the platelines and the bitlines.

### While an exemplary read and restore operation has been described above, it will be appreciated that the present invention extends to write operations and read operations.

In the description, the data bitlines are also referred as bitlines and the external data IO pins are also referred as external bitlines. Generally the polarization state of a ferroelectric capacitor refers to the capacitor polarization orientation as discussed in the FIG. 4C where as the data value refers to the read (sensed) signal on the bitline(s), sense amplifier or external bitline(s). As an example for 2T2C device, the ferroelectric capacitors are in complementary state for any data value.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of accessing a ferroelectric memory cell comprising a bitline, a plateline, a transistor and a ferroelectric capacitor, the method comprising:
performing a first memory access on the cell;
performing a second memory access on the cell;
wherein an approximately same bias is applied to the bitline and plateline of the cell for a time between the first memory access and the second memory access.

2. The method of claim 1, wherein performing the first memory access comprises:
reading a stored first data value from the cell.

3. The method of claim 2, wherein performing the second memory access comprises:
writing a second data value to the cell.

4. The method of claim 3, wherein the time between the first and second memory accesses is user-manipulatable and during which an input data signal to a memory device associated with the cell is capable of being toggled.

5. The method of claim 1, wherein the same bias is approximately zero volts.

6. The method of claim 1, wherein the same bias is approximately a supply voltage Vdd.

7. The method of claim 1, wherein the cell is associated with a memory array.

8. The method of claim 1, wherein a wordline associated with the cell is continuously asserted during the first and second memory accesses.

9. The method of claim 1, wherein performing the first memory access comprises:
reading stored data value from the cell; and
writing a first polarization state to the ferroelectric capacitor of the cell.

10. The method of claim 9, wherein performing the second memory access comprises:
selectively writing a second data value that is opposite the first data value to the ferroelectric cell.

11. The method of claim 10, wherein the time between the first and second memory access operations is user-manipulatable and during which an input data signal to a memory device associated with the cell is capable of being toggled.

12. The method of claim 1, wherein the memory cell is 1T1C.

13. The method of claim 1, wherein the memory cell is 2T2C.

14. A method of accessing a selected ferroelectric memory cell from a column of cells, wherein the column comprises: a bitline, a plurality of wordlines and a plurality of platelines, and wherein the selected cell comprises: the bitline, a first of the plurality of platelines, a transistor and a ferroelectric capacitor; the method comprising:
performing a first operation on the selected memory cell; and
performing a second operation on the selected memory cell; and
applying approximately a same bias to the bitline, and the first plateline for a time between the first operation and the second operation.

15. The method of 14 wherein approximately the same bias is applied to the bitline and a second of the plurality of platelines for the time between the first operation and the second operation.

16. The method of claim 14 wherein the plurality of platelines relates to a plurality of plate groups.

17. The method of claim 14 wherein the number of the plurality of platelines is fewer than the number of the memory cells associated with the bitline in the column.

18. The method of claim 14, wherein performing the first operation comprises:
reading a stored first data value from the selected ferroelectric memory cell.

19. The method of claim 18, wherein performing the second operation comprises:
writing a second data value to the selected ferroelectric memory cell.

20. The method of claim 19, wherein the time between the first and second operations is user-manipulatable and during which an input data signal to a memory device associated with the cell is capable of being toggled.

21. The method of claim 14, wherein the same bias is approximately zero volts.

22. The method of claim 14, wherein the same bias is approximately a supply voltage Vdd.

23. The method of claim 14, wherein the column of cells is associated with a memory array.

24. The method of claim 14, wherein a wordline associated with the selected ferroelectric memory cell is continuously asserted during the first and second memory accesses.

25. The method of claim 14, wherein performing the first operation comprises:
reading stored data value from the selected ferroelectric memory cell; and
writing a first polarization state to the ferroelectric capacitor of the selected ferroelectric memory cell.

26. The method of claim 25, wherein performing the second operation comprises:
selectively writing a second data value that is opposite the first data value to the selected ferroelectric memory cell.

27. The method of claim 26, wherein the time between the first and second operations is user-manipulatable and during which an input data signal to a memory device associated with the cell is capable of being toggled.

28. The method of claim 14, wherein the memory cell is 1T1C.

29. The method of claim 14, wherein the memory cell is 2T2C.

30. A ferroelectric memory device, comprising:
a memory array comprising one or more ferroelectric memory cells that are coupled to one or more wordlines configured to select a row of memory cells; wherein a first plateline and one or more bitlines are configured to selectively bias a selected row of memory cells during both a first memory access operation and a second memory access operation; and
a control system coupled with the memory array, the control system being adapted to apply a bias of approximately zero volts between the first plateline and one of the one or more bitlines of one or more ferroelectric memory cells during a time between the first and second memory access operations.

31. The device of claim 30, further comprising:
a set of one or more additional platelines that does not include the first plateline, but which is associated with the one or more bitlines;
wherein the control system is adapted to apply the bias of approximately zero volts between the set of one or more additional platelines and one of the one or more bitlines of one or more ferroelectric memory cells during the time between the first and second memory access operations.

32. The device of claim 30, further comprising:
one or more external bitlines associated with one or more pins of the memory device, the external bitlines capable of being toggled during the time between the first and second memory access operations.

33. The device of claim 32, wherein the control system comprises:
one or more sensing circuits adapted to both selectively couple the external bitlines to and selectively decouple the external bitlines from the one or more bitlines.

34. The device of claim 33, wherein the control system further comprises:
one or more plate group drivers adapted to activate a plateline group that comprises two or more platelines.

35. The device of claim 30, wherein the first memory access operation comprises reading a stored data value from the selected row of memory cells.

36. The device of claim 35, wherein the second memory access operation after the first memory access operation comprises restoring the read data value or writing a second data value that is opposite the first data value to the selected row of memory cells.

37. The device of claim 30, wherein the first memory access operation comprises reading a stored data value and writing a first polarization state to the ferroelectric capacitors associated with the selected row of memory cells.

38. The device of claim 37, wherein the second memory access operation after the first memory access operation comprises restoring the read data value or writing a second data value that is opposite the first data value to the selected row of memory cells.

39. The device of claim 30, wherein a user-manipulatable time exists between the first memory access operation and the second memory access operation.

40. The device of claim 30, wherein the ferroelectric memory cells are in 1T1C configuration.

41. The device of claim 30, wherein the ferroelectric memory cells are in 2T2C configuration.

42. A method for accessing ferroelectric memory cells in a ferroelectric memory device, wherein each ferroelectric memory cell comprises one or more ferroelectric capacitors; the method comprising:
performing a read and write memory access to one or more selected ferroelectric memory cells associated with a ferroelectric memory array; and
during the read and write memory access, reading a first data value from a first cell of the one or more selected memory cells, writing a first polarization state to the ferroelectric capacitors of the one or more selected cells including the first cell and then writing a second data value that is opposite the first data value to the first cell.

43. The method of claim 42, wherein a user-manipulatable time exists between the writing of the first data value and the writing of the second data value.

44. The method of claim 43, wherein during at least a portion of the user-manipulatable time, a bias of approximately zero volts is applied to a plateline and bitline associated with the one or more selected cells.

45. The method of claim 44, wherein during at least a portion of the user-manipulatable time an input signal to the memory device is capable of being toggled.

46. The method of claim 45, wherein writing the first polarization state to the ferroelectric capacitors of the selected cells comprises:
stepping a plateline from a first voltage to a second voltage while a bitline is held to the second voltage.

47. The method of claim 46 wherein the first voltage is approximately zero volts and the second voltage is approximately a supply voltage Vdd.

48. The method of claim 46 wherein the first voltage is approximately a supply voltage Vdd and the second voltage is approximately zero volts.
